(19) United States
(12) Patent Application Publication
(10) Pub. No.: US 2010/0236819 A1
(43) Pub. Date: Sep. 23, 2010

(54) PRINTED CIRCUIT BOARD AND METHOD FOR MAKING THE SAME

(75) Inventors: Wen-Chung Chiang, Lujhu Township (TW); Keng-Chung Wu, Lujhu Township (TW); Ying-Chi Hsieh, Lujhu Township (TW); Cheng-Kang Lu, Lujhu Township (TW); Ming-Huang Fu, Lujhu Township (TW)

Correspondence Address: OCCHIUTI ROHLICEK & TSAO, LLP, 10 FAWCETT STREET, CAMBRIDGE, MA, 02138, US

(73) Assignee: High Conduction Scientific Co., Ltd., Lujhu Township (TW)

(21) Appl. No.: 12/724,200

(22) Filed: Mar. 15, 2010

(30) Foreign Application Priority Data
Mar. 17, 2009 (TW) 098108574

(51) Int. Cl. H05K 1/09; B05D 5/12; B32B 38/10; H05K 1/03; H05K 1/11; G03F 7/20

(52) U.S. Cl. 174/257; 427/98.3; 156/280; 156/272.8; 174/258; 430/319

(57) ABSTRACT

A method for making a printed circuit board includes: (a) preparing a laminate having a ceramic substrate, first and second metal foils disposed on two opposite surfaces of the ceramic substrate, and a through hole extending through the ceramic substrate and the first and second metal foils; (b) filling the through hole with a metal paste such that the metal paste is in contact with the first and second metal foils; and (c) sintering the metal paste and the laminate such that the metal paste is connected electrically to the first and second metal foils. A printed circuit board made according to the method is also disclosed.

### CROSS-REFERENCE TO RELATED APPLICATION

This application claims priority of Taiwanese application no. 098108574, filed on Mar. 17, 2009.

### BACKGROUND OF THE INVENTION

1. Field of the Invention

This invention relates to a printed circuit board and a method for making the same.

2. Description of the Related Art

Conventionally, a dual-face printed circuit board including a ceramic substrate is made by: laminating a first copper foil 91 on one surface of a ceramic substrate 92 (see FIG. 1); drilling a through hole 921 in the ceramic substrate 92 (see FIG. 2) to expose the first copper foil 91 from the through hole 921; placing a copper ball 93 into the through hole 921 (see FIG. 3); laminating a second copper foil 94 on another surface of the ceramic substrate 92 that is opposite to the first copper foil 91 to enclose the copper ball 93 (see FIG. 4); and eutectic sintering the first and second copper foils 91, 94 and the ceramic substrate 93 such that the copper ball 93 is connected electrically to the first and second copper foils 91, 94. By the above method, a printed circuit board 9 as shown in FIG. 5 is manufactured.

In another method, the dual-face printed circuit board 9 is made by using a copper disk 96 (see FIG. 6) instead of the copper ball 93 and by using a step of spot welding instead of the step of eutectic sintering. As shown in FIG. 7, a portion of the second copper foil 94 corresponding to the through hole 921 is pressed against the copper disk 96 by a welding rod 97 during spot welding to weld together the first and second copper foils 91, 94 and the copper disk 96. Therefore, a printed circuit bard 9′ as shown in FIG. 8 is manufactured.

With the development of miniaturized electronic products, the through hole 921 in the printed circuit board 9, 9′ is getting smaller. Therefore, it has become more difficult to place the copper ball 93 or the copper disk 96 into the through holes 921. The precision requirement for spot welding is also getting higher. Furthermore, the diameter of the copper ball 93 should be a little larger than the depth of the through hole 921, since the surface of the copper foil will be uneven when the diameter of the copper ball 93 is too large, and since a faulty circuit is likely to occur when the diameter of the copper ball 93 is too small. Therefore, the precision for the size of the copper ball 93 is increasingly stringent.

Accordingly, in practice, the through hole 921 in the printed circuit board 9 or 9′ has a lower limit of 1 mm. There is a need to develop a method for making a printed circuit board having a smaller through hole to satisfy the requirement of current electronic devices.

### SUMMARY OF THE INVENTION

Therefore, an object of the present invention is to provide a printed circuit board and a method for making the same that can overcome the aforesaid drawbacks associated with the prior art.

According to one aspect of this invention, a method for ma king a printed circuit board is provided. The method comprises:

(a) preparing a laminate having a ceramic substrate, first and second metal foils disposed on two opposite surfaces of the ceramic substrate, and a through hole extending through the ceramic substrate and the first and second metal foils;

(b) filling the through hole with a metal paste such that the metal paste is in contact with the first and second metal foils; and

(c) sintering the metal paste and the laminate such that the metal paste is connected electrically to the first and second metal foils.

According to another aspect of this invention, a printed circuit board is provided. The printed circuit board comprises:

a ceramic substrate;

first and second metal foils respectively disposed on two opposite surfaces of the ceramic substrate;

a through hole having a diameter ranging from 0.2 mm to 1 mm and extending through the ceramic substrate, and the first and second metal foils; and

a conductive pillar disposed in the through hole and integrated with the first and second metal foils for electrical connection with each other.

Preferably, each of the first and second metal foils is a copper foil.

### BRIEF DESCRIPTION OF THE DRAWINGS

Other features and advantages of the present invention will become apparent in the following detailed description of the preferred embodiments of the invention, with reference to the accompanying drawings, in which:

FIGS. 1 to 5 show successive steps of a conventional method for making a printed circuit board;

FIGS. 6 to 8 show successive steps of another conventional method for making a printed circuit board;

FIG. 9 is a cross-sectional view of a printed circuit board according to the first embodiment of the present invention;

FIG. 10 is a flow chart showing a method for making a printed circuit board according to the first embodiment of the present invention;

FIG. 11 is a cross-sectional view of a laminate having a ceramic substrate and first and second copper foils disposed on two opposite surfaces of the ceramic substrate;

FIG. 12 is a cross-sectional view illustrating the laminate of FIG. 11 after being etched to form two end portions for each through hole;

FIGS. 13 to 18 show successive steps for forming the end portions of each through hole in the method for making a printed circuit board according to the first embodiment of the present invention;

FIG. 19 is a cross-sectional view illustrating the laminate of FIG. 12 after being formed with a middle portion for each through hole, the middle portion being aligned with the end portions of the through hole;

FIG. 20 is a cross-sectional view of a printed circuit board before a sintering step of the method for making a printed circuit board according to the first embodiment of the present invention; and

FIG. 21 is a flow chart showing a method for making a printed circuit board according to the second embodiment of the present invention.

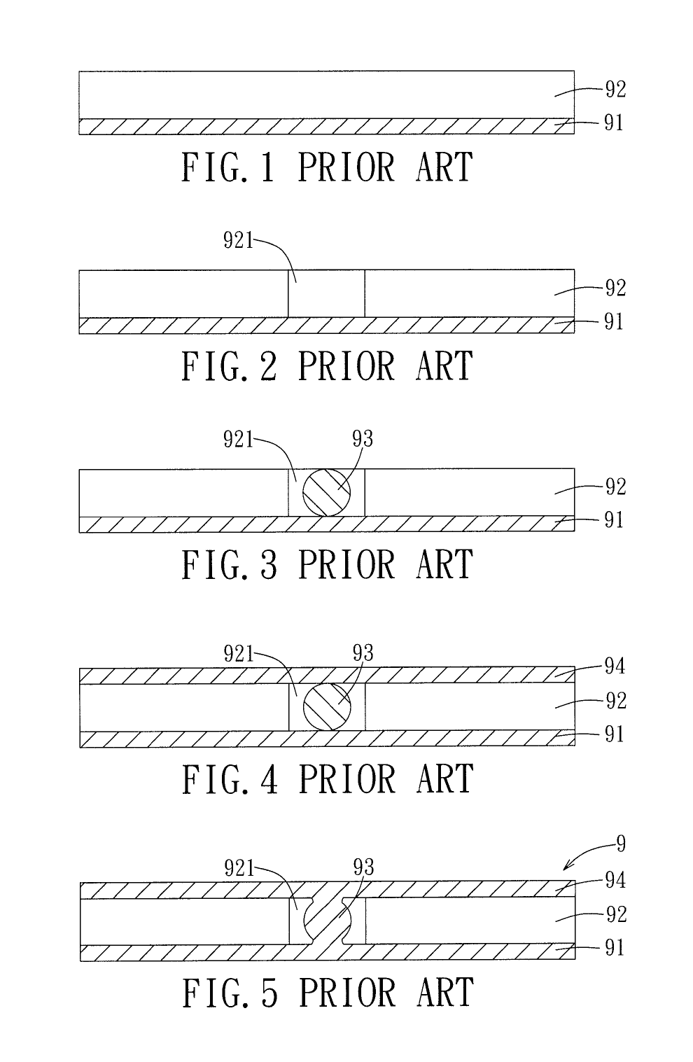

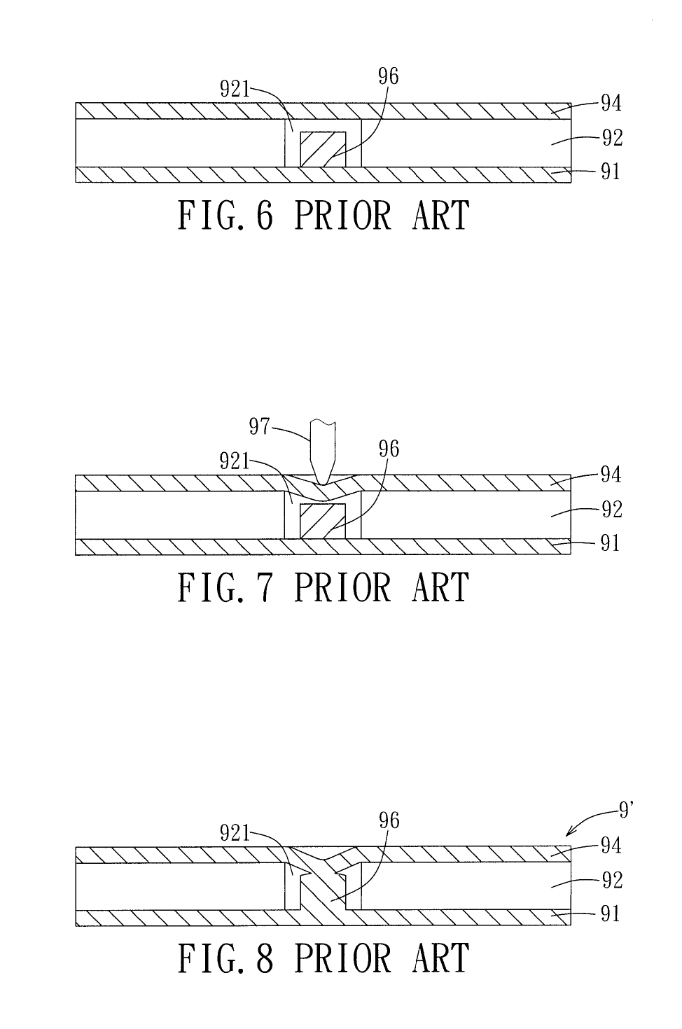

### DETAILED DESCRIPTION OF THE PREFERRED EMBODIMENTS

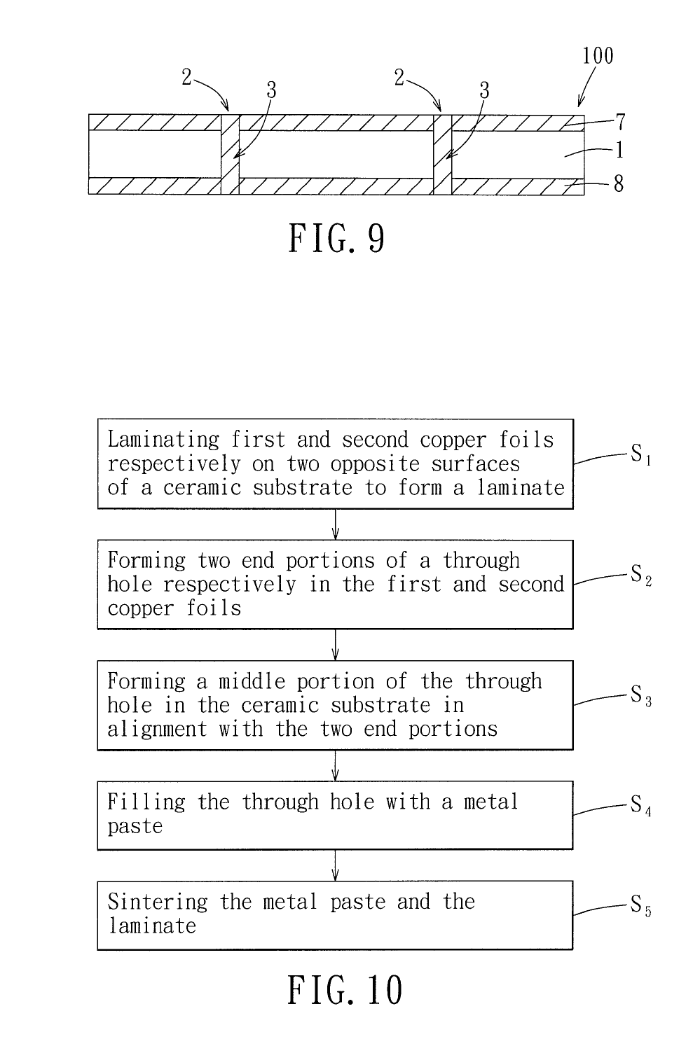

Referring to FIG. 9, a printed circuit board 100 according to the first embodiment of the present invention is shown to comprise: a ceramic substrate 1, first and second copper foils 7 and 8, four through holes 2 (only two are shown in FIG. 9) and four conductive pillars 3 (only two are shown in FIG. 9) respectively disposed in the through holes 2.

The ceramic substrate 1 has a thickness of 0.635 mm, and is made of aluminium oxide (Al₂O₃). In other embodiments, the ceramic substrate 1 can be made of aluminium nitride (AlN), zirconium oxide (ZrO₂), or titanium oxide (TiO₂). The first and second metal foils 7 and 8 are respectively disposed on two opposite surfaces of the ceramic substrate 1. Each of the through holes 2 has a diameter ranging from 0.2 mm to 1 mm and extends through the ceramic substrate 1, and the first and second copper foils 7 and 8. Each of the conductive pillars 3 is disposed in one of the through holes 2 and is integrated with the first and second copper foils 7 and 8 for electrical connection with each other.

The numbers and positions of the through holes 2 and the conductive pillars 3 can be varied based on the circuit design of the printed circuit board 100.

Each of the conductive pillars 3 is a sinter of a metal paste 31 (see FIG. 20). The metal paste 31 includes: copper powder in an amount ranging from 80 to 90 wt %; a binder in an amount ranging from 1 to 10 wt %; and a diluent in an amount ranging from 1 to 10 wt %. The copper powder has a particle diameter ranging from 1 μm to 50 μm. The binder is terpineol, and the diluent is one of ethanol and isopropanol.

FIG. 10 illustrates a flow chart for making the printed circuit board 100 according to the first embodiment of the present invention.

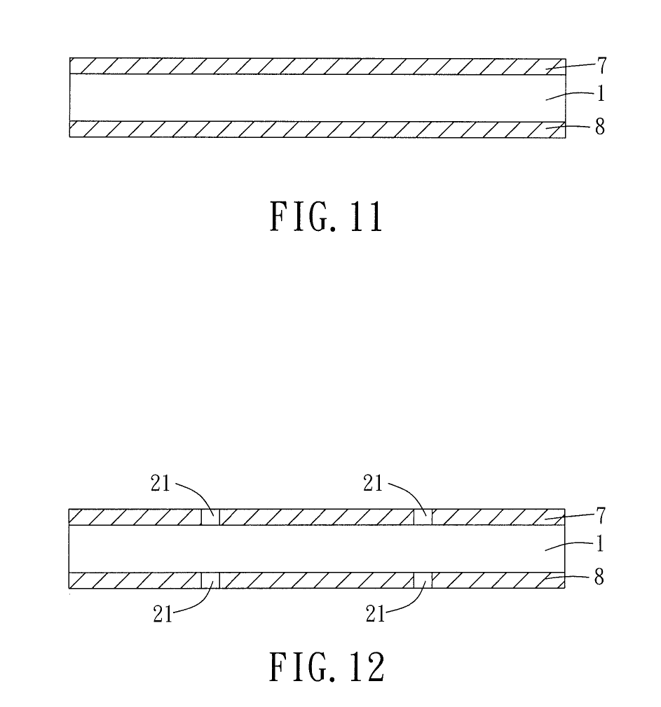

In step S1, the first and second copper foils 7 and 8 are laminated respectively on the two opposite surfaces of the ceramic substrate 1 (see FIG. 11) using a direct copper bonding process.

Steps S2 and S3 are employed for forming the through holes 2 (see FIG. 9). Because the ceramic substrate 1 of the printed circuit board 100 is thin (only 0.635 mm), it is likely to break if the through holes 2 are formed by a normal mechanical drilling process. Therefore, the through holes 2 in the printed circuit board 100 are formed by two steps S2 and S3.

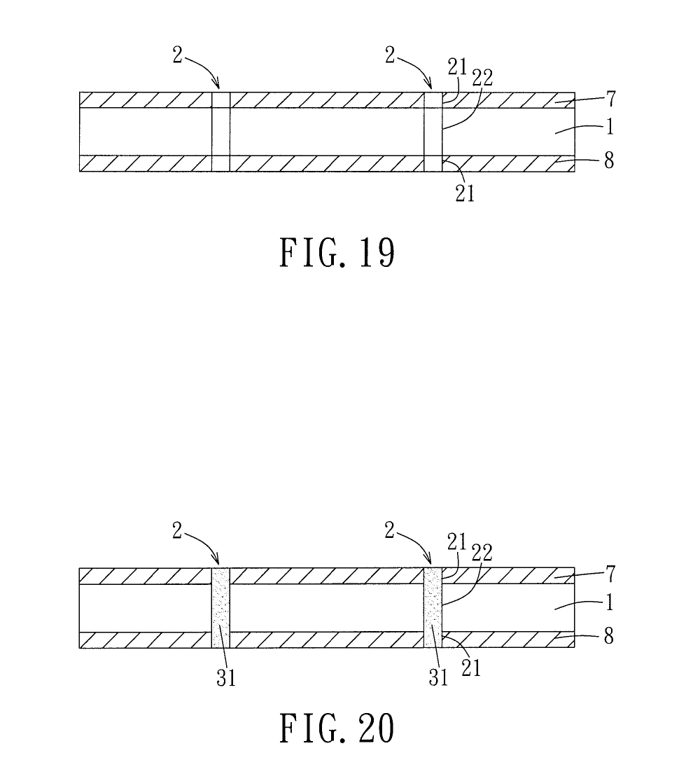

As shown in FIG. 19, each of the through holes 2 is divided into three portions, i.e., an end portion 21 in the first copper foil 7, a middle portion 22 in the ceramic substrate 1, and another end portion 21 in the second copper foil 8. The two end portions 21 of each of the through holes 2 are formed in the step S2, and the middle portion 22 of each of the through holes 2 is formed in the step S3.

In the step S2, the two end portions 21 of each of the through holes 2 in the first and second copper foils 7 and 8 are formed by a lithography patterning process.

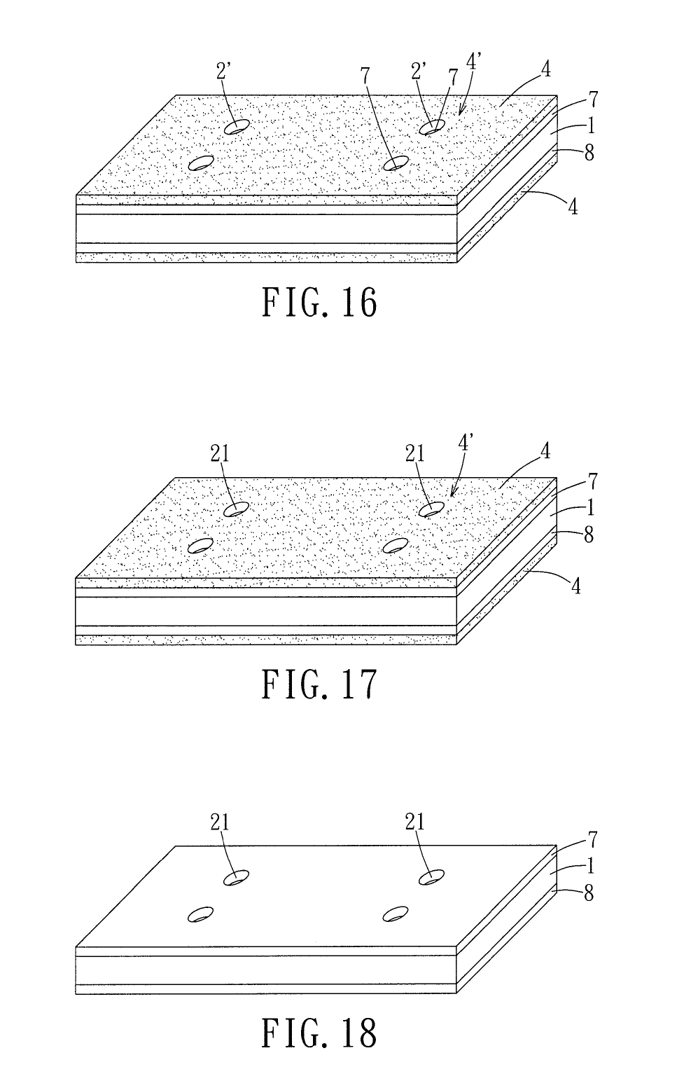

The lithographic patterning process includes: (1) lithography printing the first and second copper foils 7 and 8 to form pre-patterns 4′ (see FIG. 16); (2) etching the pre-patterns 4′ to form the two end portions 21 of each of the through holes 2 respectively in the first and second copper foils 7 and 8 (see FIG. 17); and (3) removing the pre-patterns 4′ from the first and second copper foils 7 and 8 (see FIG. 18).

As shown in FIG. 16, each of the pre-patterns 4′ has four regions 2′, each of which corresponds to one of the two end portions 21 of each of the through holes 2.

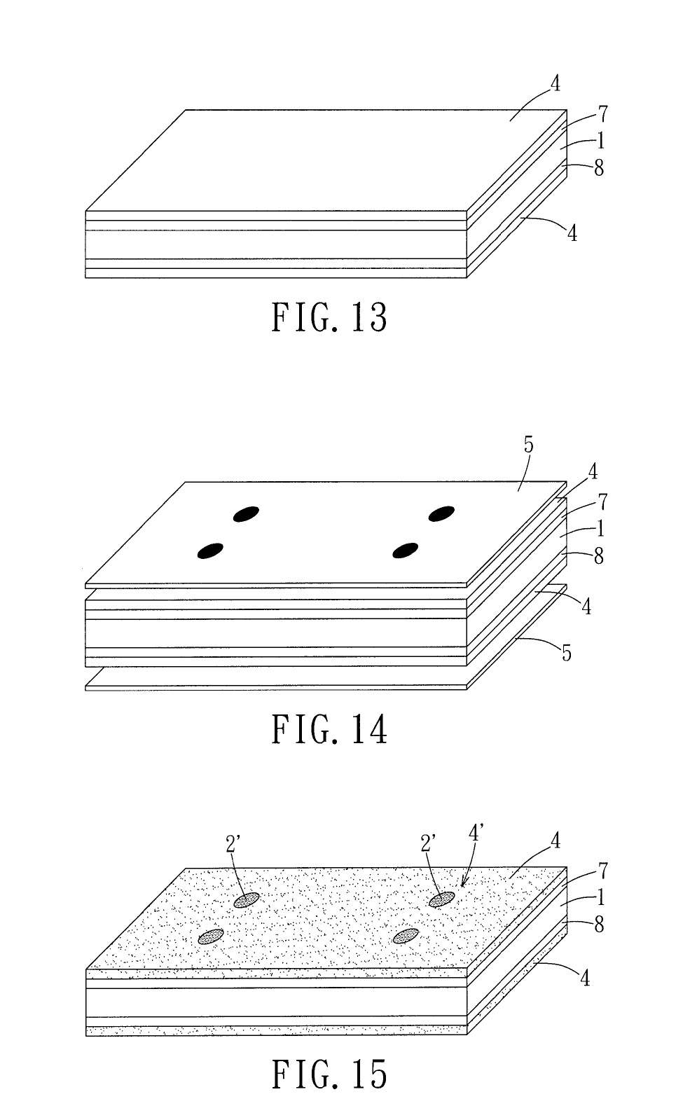

In the step (1), each of the pre-patterns 4′ is formed on one of the first and second copper foils 7 and 8 by the following sub-steps: (a) disposing a dry film resist 4 on the corresponding one of the first and second copper foils 7 and 8 (see FIG. 13); (b) disposing a negative 5 of the pre-pattern on the dry film resist 4 (see FIG. 14); (c) exposing the dry film resist 4 to form the pre-pattern 4′ which has four unexposed regions 2′ corresponding to four end portions 21 of the through holes 2 (see FIG. 15); and (d) developing the dry film resist 4 so that the unexposed regions 2′ of the dry film resist 4 are removed to form four exposed regions 2′ to expose four parts of the first or second copper foil 7 or 8 thereunder (see FIG. 16).

The sub-step (c) is conducted by using a UV light to cure the dry film resist 4 through the negative 5. The sub-step (d) is conducted by using a developer including a Na₂CO₃ solution. The etching step (2) is conducted by using a ferric chloride etchant or a cupric chloride etchant. The removal step (3) is conducted by using a stripper including a NaOH solution.

Although, in this embodiment, only the method for forming the end portions 21 of the through holes 2 is described in the lithography patterning process, the circuits of the printed circuit board 100 can be also made at the same time based on the design of the printed circuit board 100.

In the step S3, a middle portion 22 of each of the through holes 2 is formed in the ceramic substrate 1 in alignment with the two end portions 21 of the corresponding through hole 2. The step S3 is conducted by a laser drilling process since the through holes 2 are smaller than 1 mm, and since the ceramic substrate 1 is likely to break using the conventional mechanical drilling process. Furthermore, a post treatment of the conventional mechanical drilling process is not necessary for the laser drilling process.

After the step S3, the two end portions 21 of each of the through holes 2 are connected by the respective middle portion 22.

In step S4, the through holes 2 are filled with the metal paste 31 such that the metal paste 31 is in contact with the first and second copper foils 7 and 8 (see FIG. 20).

In step S5, the metal paste 31 and the laminate are sintered at a sintering temperature ranging from 800° C. to 1075° C. to form the conductive pillar 3 that is connected electrically to the first and second copper foils 7 and (see FIG. 9).

Because the metal paste 31 is a viscous fluid that has good flowability and plasticity, it can flow into the through holes 2 even though the diameter of the through holes 2 is smaller than 1 mm. Since the metal paste 31 can be formed into the conductive pillars 3 by filling the through holes 2 followed by sintering, it is not necessary to preform the metal paste 31 with precise dimensions that is required for the copper ball used in the prior art. In practice, when the diameter of the through holes 2 is 0.2 mm, the yield rate of the printed circuit board 100 is up to 90%. Of course, the method according to the first embodiment of the present invention can also be conducted for making a printed circuit board having through holes, each having a diameter larger than 1 mm.

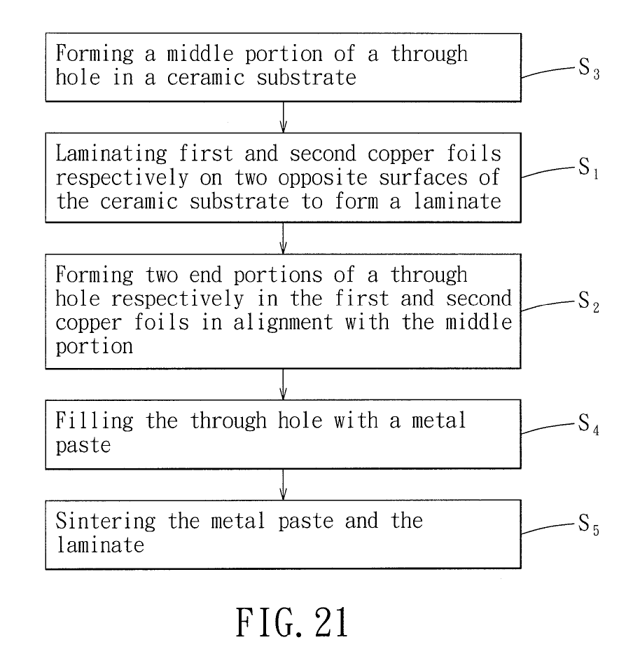

FIG. 21 illustrates a flow chart for making the printed circuit board 100 according to the second embodiment of the present invention. The second embodiment differs from the first embodiment only in that the step S3 is conducted before the steps S1 and S2. In particular, a middle portion 22 of each of the through holes 2 is formed in the ceramic substrate 1 before the first and second copper foils 7 and 8 are laminated with the ceramic substrate 1. Thereafter, the two end portions 21 of each of the through holes 2 are formed respectively in the first and second copper foils 7, 8 in alignment with the corresponding middle portion 22.

While the present invention has been described in connection with what are considered the most practical and preferred embodiments, it is understood that this invention is not limited to the disclosed embodiments but is intended to cover various arrangements included within the spirit and scope of the broadest interpretations and equivalent arrangements.

What is claimed is:

1. A method for making a printed circuit board, comprising:
(a) preparing a laminate having a ceramic substrate, first and second metal foils disposed on two opposite surfaces of the ceramic substrate, and a through hole extending through the ceramic substrate and the first and second metal foils;
(b) filling the through hole with a metal paste such that the metal paste is in contact with the first and second metal foils; and
(c) sintering the metal paste and the laminate such that the metal paste is connected electrically to the first and second metal foils.

2. The method of claim 1, where the step (a) includes:
(a1) laminating the first and second metal foils respectively on the two opposite surfaces of the ceramic substrate;
(a2) forming two end portions of the through hole respectively in the first and second metal foils; and
(a3) forming a middle portion of the through hole in the ceramic substrate such that the middle portion is aligned with the two end portions.

3. The method of claim 2, wherein the two end portions of the through hole in the first and second metal foils are formed by a lithography patterning process.

4. The method of claim 3, wherein the lithography patterning process includes: lithographic printing the first and second metal foils to form pre-patterns each of which has a region corresponding to one of the two end portions of the through hole; and etching the pre-patterns to form the two end portions of the through hole respectively in the first and second metal foils.

5. The method of claim 4, wherein each of the pre-patterns is formed on one of the first and second metal foils by disposing a dry film resist on the corresponding one of the first and second metal foils, disposing a negative of the pre-pattern on the dry film resist, exposing the dry film resist to form the pre-pattern which has an unexposed region corresponding to one of the two end portions of the through hole, and developing the dry film resist so that the unexposed region of the dry film resist is removed to expose a part of the first or second metal foil thereunder.

6. The method of claim 5, wherein the part of the first or second metal foil exposed from the dry film resist is etched until the ceramic substrate is exposed, and the exposed region of the dry film resist is removed.

7. The method of claim 2, wherein the middle portion is formed by a laser drilling process.

8. The method of claim 2, where the step (a3) is conducted before the steps (a1, a2).

9. The method of claim 2, where the step (a1) is conducted before the steps (a2) and (a3).

10. The method of claim 2, wherein the step (c) is conducted at a sintering temperature ranging from 800° C. to 1075° C.

11. The method of claim 1, wherein each of the first and second metal foils is a copper foil.

12. The method of claim 1, wherein the metal paste includes:
copper powder in an amount ranging from 80 to 90 wt %;
a binder in an amount ranging from 1 to 10 wt %; and
a diluent in an amount ranging from 1 to 10 wt %.

13. A printed circuit board, comprising:
a ceramic substrate;
first and second metal foils respectively disposed on two opposite surfaces of said ceramic substrate;
a through hole having a diameter ranging from 0.2 mm to 1 mm and extending through said ceramic substrate, and said first and second metal foils; and
a conductive pillar disposed in said through hole and integrated with said first and second metal foils for electrical connection with each other.

14. The printed circuit board of claim 13, wherein said conductive pillar is a sinter of a metal paste including:
copper powder in an amount ranging from 80 to 90 wt %;
a binder in an amount ranging from 1 to 10 wt %; and
a diluent in an amount ranging from 1 to 10 wt %.

15. The printed circuit board of claim 14, wherein said copper powder has a particle diameter ranging from 1 μm to 50 μm.

16. The printed circuit board of claim 14, wherein said binder is terpineol.

17. The printed circuit board of claim 14, wherein said diluent is one of ethanol and isopropanol.

18. The printed circuit board of claim 13, wherein each of said first and second metal foils is a copper foil.

19. The printed circuit board of claim 13, wherein said ceramic substrate is made of aluminium oxide (Al₂O₃), aluminium nitride (AlN), zirconium oxide (ZrO₂), or titanium oxide (TiO₂).
